(19) United States
(12) Patent Application Publication
(10) Pub. No.: US 2009/0152626 A1
(43) Pub. Date: Jun. 18, 2009

(54) Super Halo Formation Using a Reverse Flow for Halo Implants

(75) Inventors: Ramesh Venugopal, Richardson, TX (US); Srinivasan Chakravarthi, Murphy, TX (US); Chris Bowen, Lucas, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/959,032

(22) Filed: Dec. 18, 2007

(51) Int. Cl. H01L 27/092; H01L 21/8238

(52) U.S. Cl. 257/338; 438/217; 257/E27.062; 257/E21.632

(57) ABSTRACT

Shrinking dimensions of MOS transistors in integrated circuits requires tighter distributions of dopants in pocket regions from halo ion implant processes. In conventional fabrication process sequences, halo dopant distributions spread during source/drain anneals. The instant invention is a method of fabricating MOS transistors in an integrated circuit in which halo ion are performed after source/drain anneals. In the inventive method, source/drain spacers on MOS gate sidewalls are removed prior to halo ion implant processes. Spacers to offset metal silicide are formed after halo implants and may be of low-k dielectric material to reduce gate to drain capacitance. A compressive stress layer may be deposited on MOS gates after source/drain spacers are removed for greater stress transfer efficiency to the MOS gates. An integrated circuit embodying the inventive method is also disclosed.

### FIELD OF THE INVENTION

This invention relates to the field of integrated circuits. More particularly, this invention relates to methods for halo implants to improve transistor short channel effects.

### BACKGROUND OF THE INVENTION

It is well known that dimensions of features in integrated circuits (ICs), including dimensions of structures in MOS transistors, are shrinking with each new fabrication technology generation, as articulated in Moore's Law. MOS transistors include medium doped drain (MDD) elements and source-drain elements (S/D), both of which are formed by ion implanting dopant atoms. The MDD elements are located close to the transistor channels under the transistor gates, and require precise distributions of dopant atoms. In particular, the halo implant in the MDD is closest to the transistor channel. The process of ion implanting creates damage in the semiconductor crystal lattice, which must be repaired by thermal annealing to obtain satisfactory values of transistor performance parameters such as on-state drive current, off-state leakage current and drain induced barrier lowering (DIBL). During a thermal anneal process, the ion implanted dopant atoms diffuse through the semiconductor, causing the profile of the dopants to degrade. Additional anneals exacerbate the degradation of the dopant profile. Commonly used fabrication process sequences ion implant MDD elements and anneal the damage from the MDD ion implant before ion implanting and annealing the S/D elements, putting the dopant atoms in the MDD elements through two anneals. As transistor feature dimensions in advanced ICs decrease, diffusion lengths of dopants in MDD elements need to scale accordingly to avoid adversely impacting transistor performance.

### SUMMARY OF THE INVENTION

This summary is provided to comply with 37 C.F.R. §1.73, requiring a summary of the invention briefly indicating the nature and substance of the invention. It is submitted with the understanding that it will not be used to interpret or limit the scope or meaning of the claims.

The instant invention is an integrated circuit and a method of fabricating same, in which halo ion implants to form pocket regions in MOS transistors are performed after source/drain anneals. Additionally, source/drain spacers on MOS gate sidewalls are removed prior to halo ion implant processes. Spacers to offset metal silicide are formed after halo implant processes are completed, and may be formed of low-k dielectric material. Additionally, spacers to offset metal silicide may be thinner than source/drain spacers, to enable optimization of source drain junction placement and silicide placement independently. A stress layer may be deposited on MOS gates after source/drain spacers are removed.

### DESCRIPTION OF THE VIEWS OF THE DRAWING

FIG. 1A through FIG. 1J are cross-sections of an integrated circuit (IC) during a process sequence for forming an NMOS transistor and a PMOS transistor according to an embodiment of the instant invention.

FIG. 2A through FIG. 2G are cross-sections of an integrated circuit (IC) during a process sequence for forming an NMOS transistor and a PMOS transistor according to another embodiment of the instant invention.

FIG. 3 is a cross-section of an IC with NMOS and PMOS transistors, after formation of NSD, PSD, NMDD, PMDD, and NMOS pocket and PMOS pocket elements, in which a stress layer is applied to the NMOS and PMOS transistors, in a further embodiment of the instant invention.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

An n-channel metal oxide semiconductor transistor will be referred to as an NMOS transistor in this disclosure. Similarly, a p-channel metal oxide semiconductor transistor will be referred to as a PMOS transistor in this disclosure. MOS transistors include source and drain regions that have medium or lightly doped drain elements, which will be referred to as MDD elements in this disclosure. An MDD element in an NMOS transistor will be referred to as an NMDD, and an MDD element in a PMOS transistor will be referred to as a PMDD. The source and drain regions of an MOS transistor also include source and drain elements, hereafter referred to as S/D elements. An S/D element in an NMOS transistor will be referred to as an NSD, and an S/D element in a PMOS transistor will be referred to as a PSD. It is common to implant p-type dopants into an NMOS transistor to form p-type regions between NMDD regions and a channel region under a gate of the NMOS transistor; such p-type regions are referred to as NMOS pocket regions in this disclosure. Similarly, it is common to implant n-type dopants into an PMOS transistor to form n-type regions between PMDD regions and a channel region under a gate of the PMOS transistor; such n-type regions are referred to as PMOS pocket regions in this disclosure.

Low-k dielectric material refers to insulating material having a dielectric constant less than 3.0, such as organo-silicate glass, carbon doped silicon dioxide or insulating material prepared from methylsilsesquioxane.

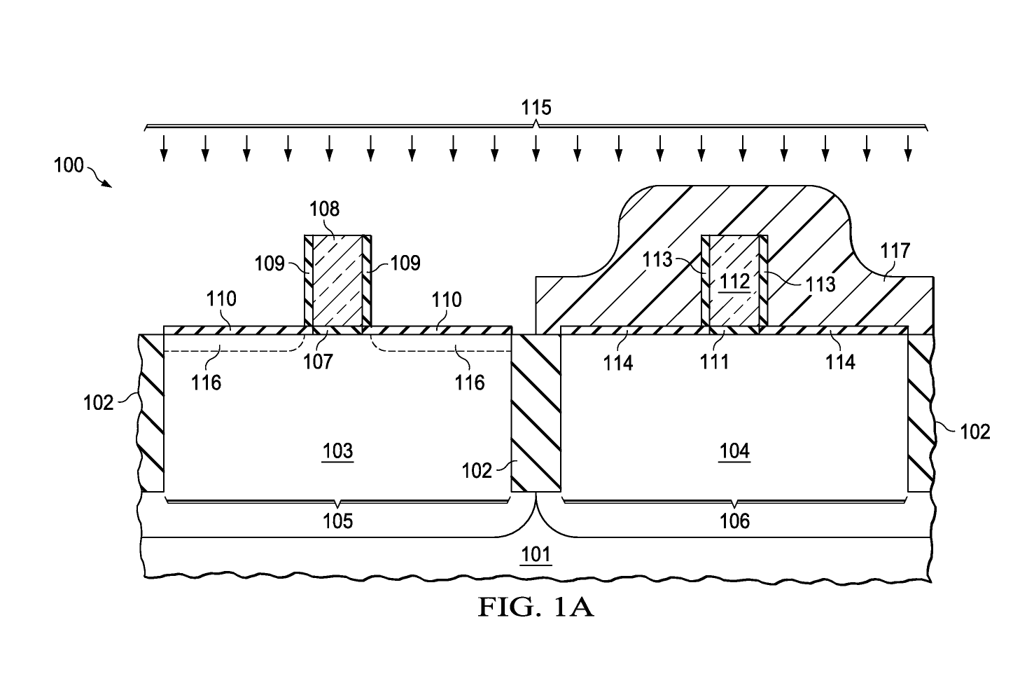

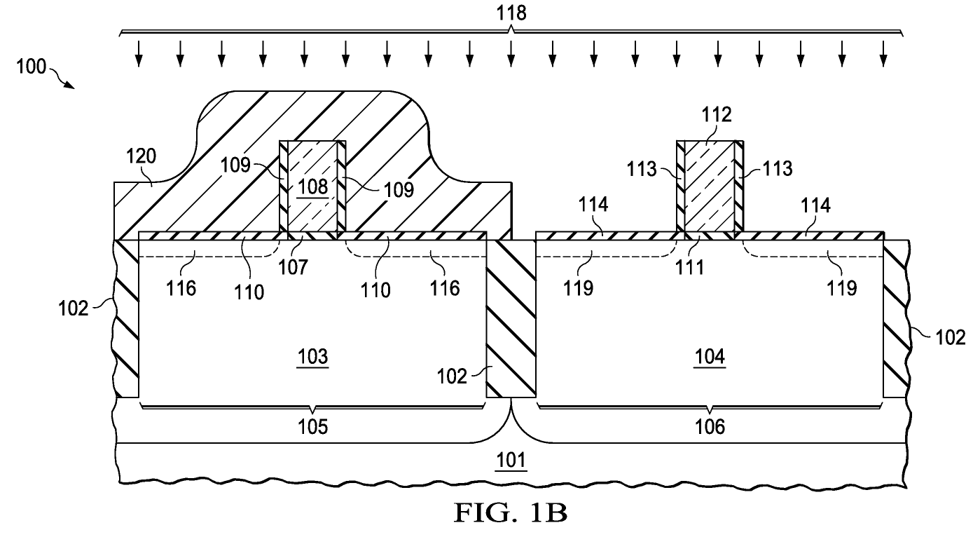

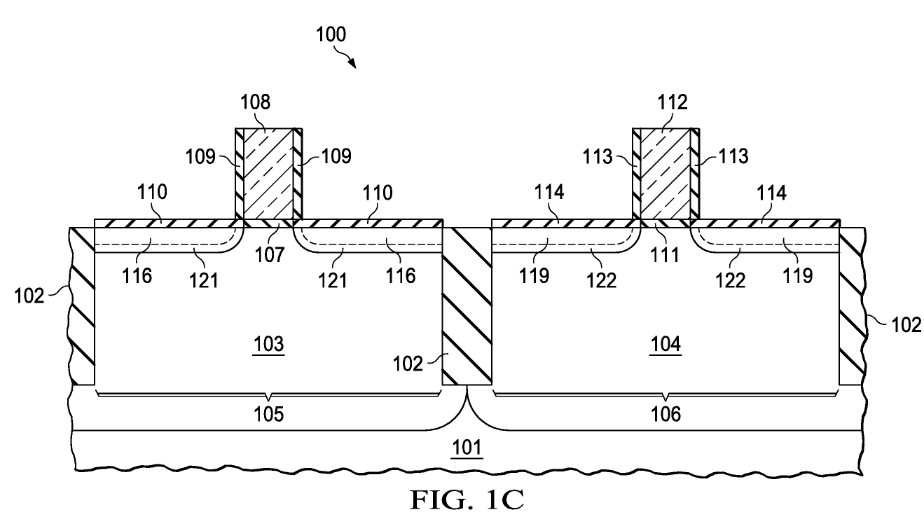

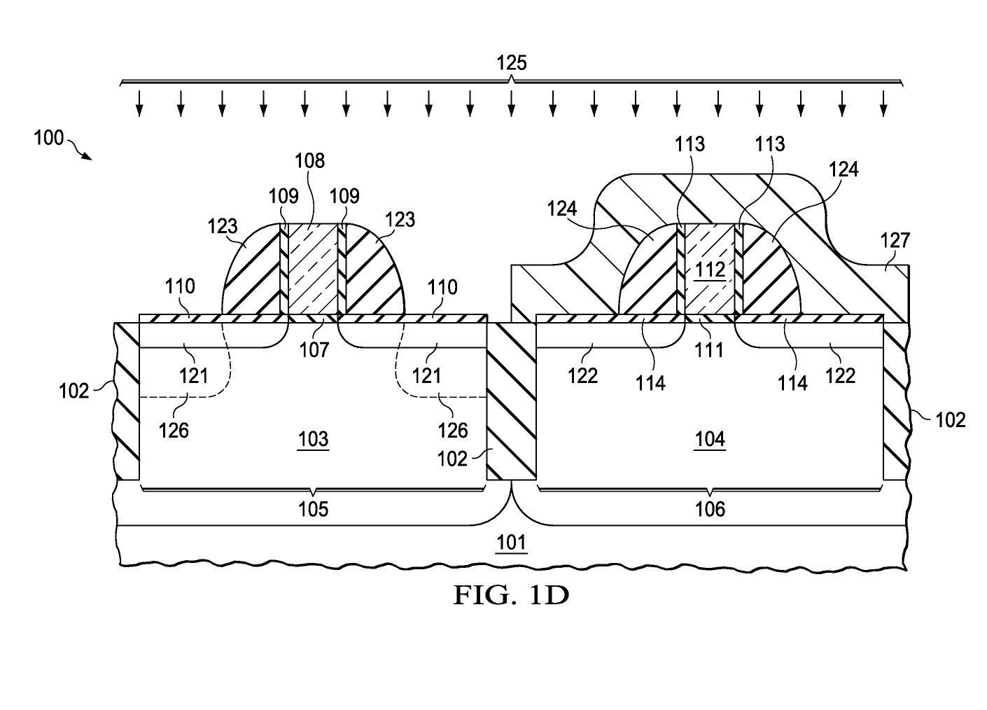

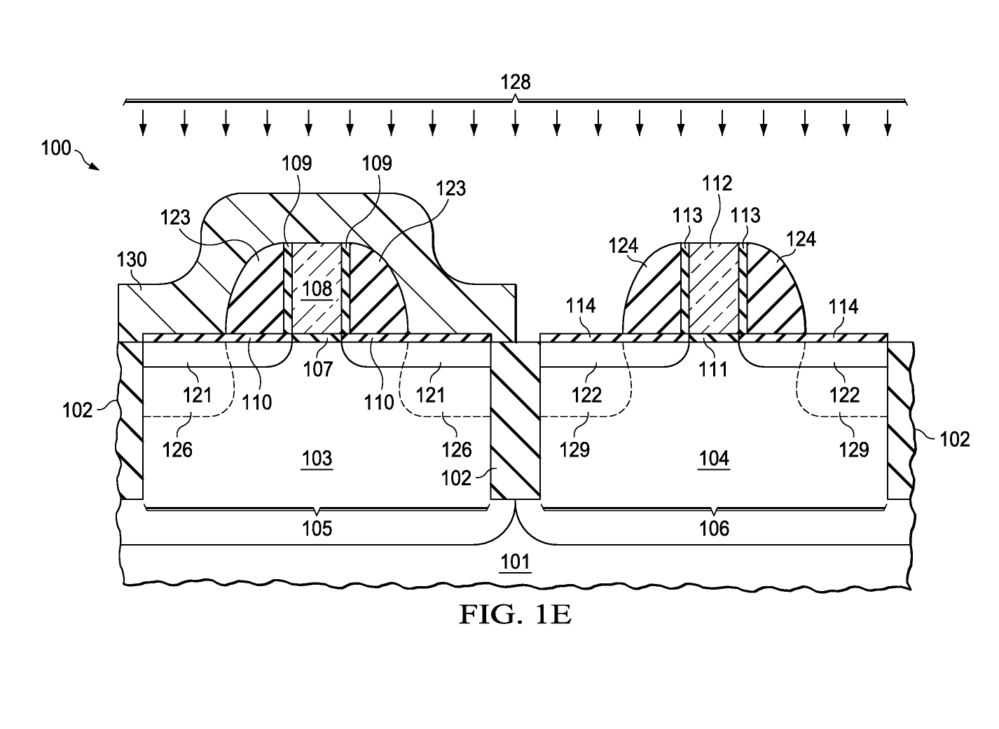

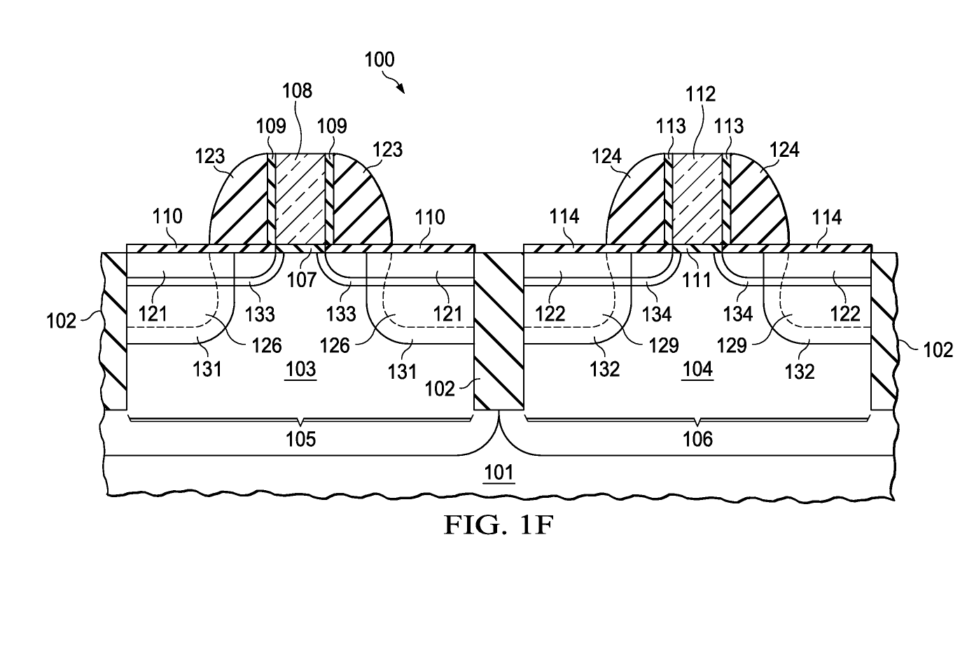

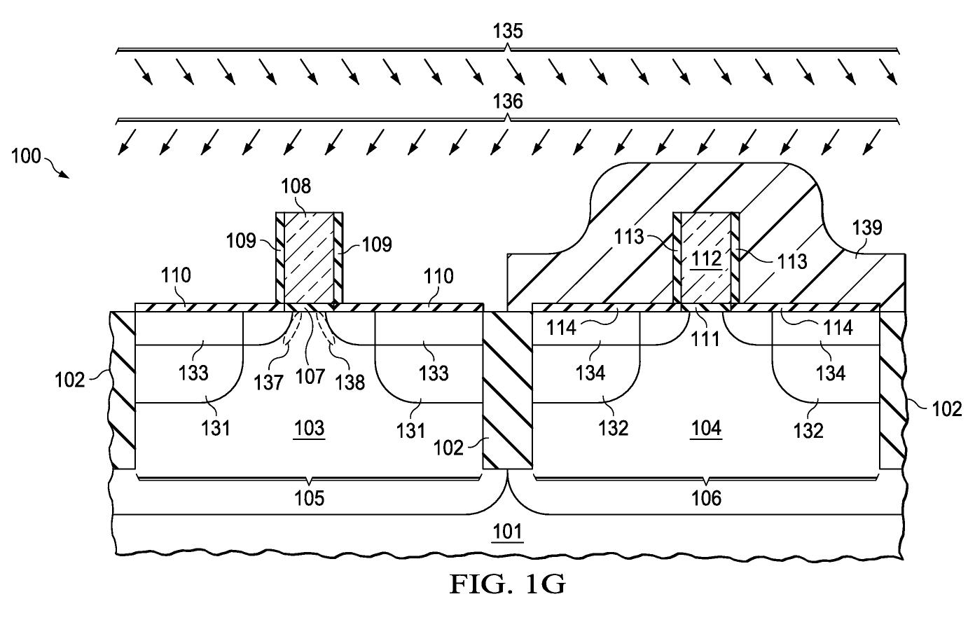

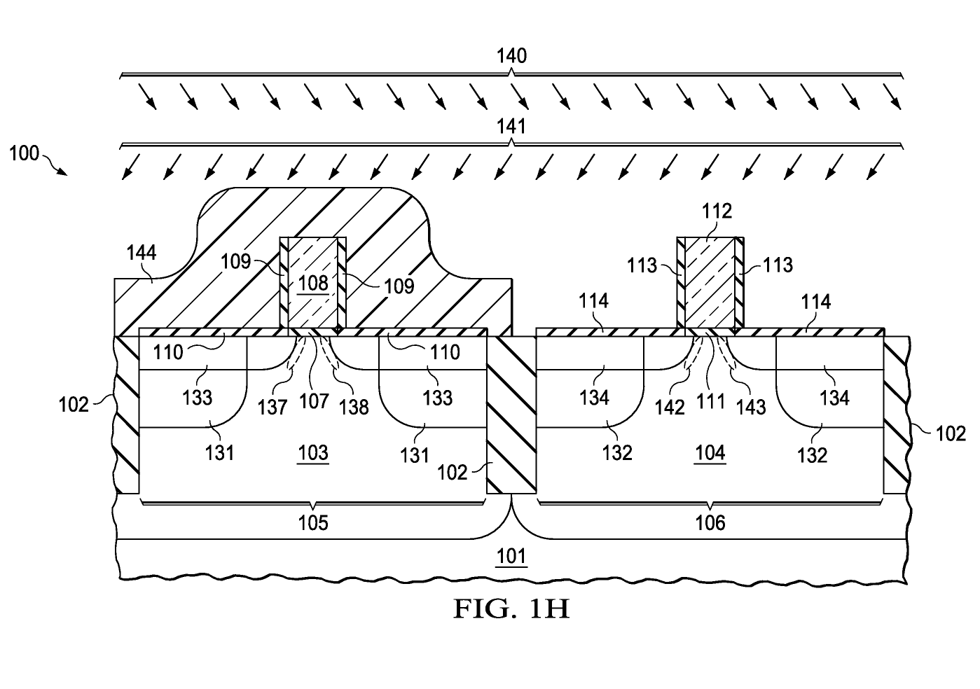

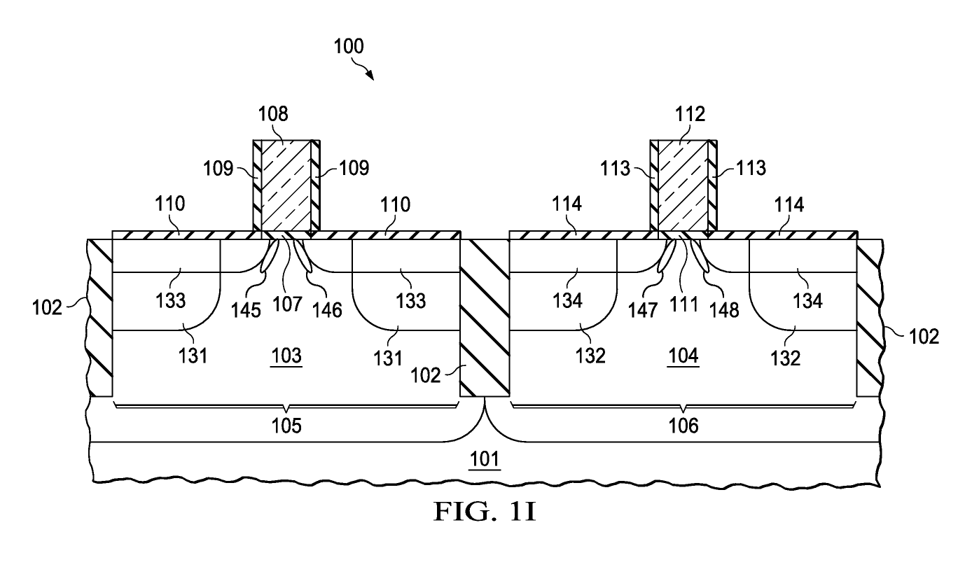

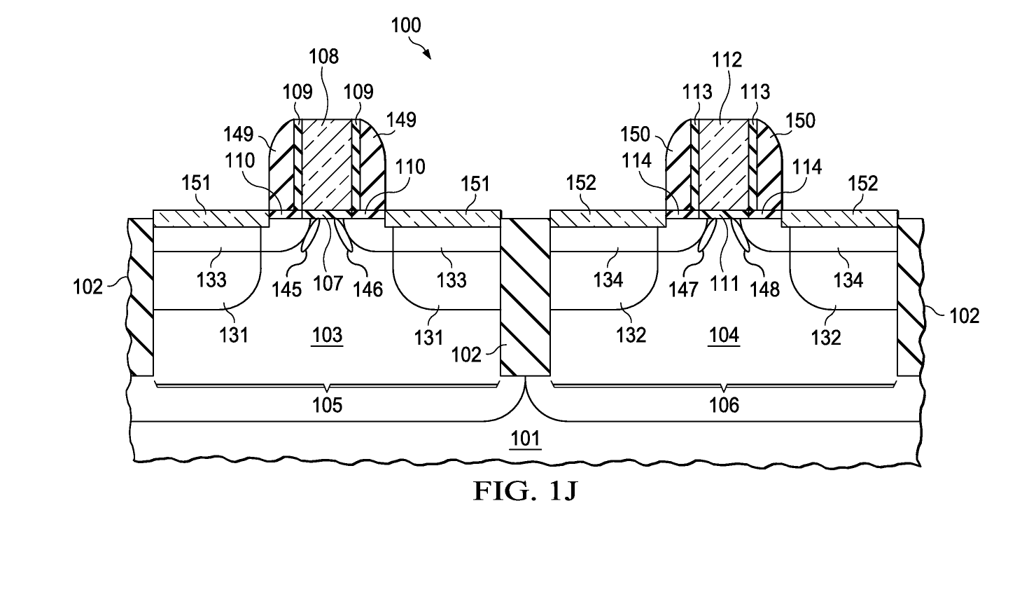

FIG. 1A through FIG. 1J are cross-sections of an integrated circuit (IC) during a process sequence for forming an NMOS transistor and a PMOS transistor according to an embodiment of the instant invention.

FIG. 1A and FIG. 1B depict the IC during MDD ion implant operations. Referring to FIG. 1A, the IC (100) includes a semiconductor substrate (101), in which are formed regions of field oxide (102), typically of silicon dioxide by shallow trench isolation (STI), to electrically isolate components such as transistors in the IC (100). A p-type region known as a p-well (103) is formed in the substrate (101) extending to a top surface of the substrate (101). Similarly, an n-type region known as an n-well (104) is formed in the substrate (101) extending to the top surface of the substrate (101). The p-well (103) and the n-well (104) are separated at the top surface of the substrate (101) by a region of field oxide (102). The NMOS transistor (105) will be formed in a region of the p-well, and the PMOS transistor (106) will be formed in a region of the n-well. The NMOS transistor includes an NMOS gate dielectric (107), typically silicon dioxide, silicon oxy-nitride, hafnium oxide, layers of silicon dioxide and silicon nitride, or other insulating material, an NMOS gate (108), typically polycrystalline silicon, NMDD spacers (109), typically layers of silicon dioxide, silicon nitride or both, formed by oxidation of the NMOS gate (108) or deposition of silicon dioxide or silicon nitride followed by an anisotropic etchback process, on lateral surfaces of the NMOS gate (108). The NMDD spacers (109) are typically less than 20 nanometers thick. A layer of NMOS moat silicon dioxide (110) is on the top surface of the p-well adjacent to the NMOS gate (108). The PMOS transistor includes an PMOS gate dielectric (111), typically silicon dioxide, silicon oxy-nitride, hafnium oxide, layers of silicon dioxide and silicon nitride, or other insulating material, an PMOS gate (112), typically polycrystalline silicon, PMDD spacers (113), typically layers of silicon dioxide, silicon nitride or both, formed by oxidation of the PMOS gate (112) or deposition of silicon dioxide or silicon nitride followed by another anisotropic etchback process, on lateral surfaces of the PMOS gate (112). The PMDD spacers (113) are typically less than 20 nanometers thick. A layer of PMOS moat silicon dioxide (114) is on the top surface of the p-well adjacent to the PMOS gate (112). N-type dopant atoms (115), such as phosphorus and arsenic, are being implanted into the NMOS transistor (105) at the top surface of the p-well (103) adjacent to the NMOS gate (108), forming an as-implanted NMDD region (116) in which a concentration of n-type dopants exceeds a concentration of p-type dopants. Ion implantation of the n-type dopant atoms (115) causes lattice damage to the p-well in the as-implanted NMDD region (116). The implanted n-type dopant atoms (115) are blocked from the PMOS transistor (106) by a first photoresist layer (117).

FIG. 1B depicts the IC (100) during a PMDD implant. P-type dopant atoms (118), such as boron and/or gallium, are being implanted into the PMOS transistor (106) at the top surface of the n-well (104) adjacent to the PMOS gate (112), forming an as-implanted PMDD region (119) in which a concentration of p-type dopants exceeds a concentration of n-type dopants. Ion implantation of the p-type dopant atoms (118) causes lattice damage to the n-well in the as-implanted PMDD region (119). The implanted p-type dopant atoms (118) are blocked from the NMOS transistor (105) by a second photoresist layer (120).

It is within the scope of the instant invention to exchange the order of the NMDD and PMDD ion implant operations.

FIG. 1C depicts the IC (100) after an MDD anneal operation to repair the lattice damage in the as-implanted NMDD region (116) and in the as-implanted PMDD region (119). In a preferred embodiment, the anneal operation is performed in a rapid thermal processor using known techniques, in order to achieve a high percentage of activation of implanted dopant atoms. This is advantageous because a higher percentage of activation produces a lower series resistance in the transistor, which results in a higher on-state drive current. In the NMOS transistor (105), implanted n-type dopant atoms in the as-implanted NMDD region (116) diffuse during the anneal operation, so that a region after anneal in which the concentration of n-type dopant atoms exceeds the concentration of p-type dopants atoms, designated as a post-MDD anneal NMDD region (121) extends further into the p-well (103) than the as-implanted NMDD region (116). Similarly, in the PMOS transistor (106), implanted p-type dopant atoms in the as-implanted PMDD region (119) diffuse during the anneal operation, so that a region after anneal in which the concentration of p-type dopant atoms exceeds the concentration of n-type dopants atoms, designated as a post-MDD anneal PMDD region (122) extends further into the n-well (104) than the as-implanted PMDD region (119).

FIG. 1D and FIG. 1E depict the IC during S/D ion implant operations. Referring to FIG. 1D, NSD spacers (123) have been formed of silicon dioxide, silicon nitride, and/or other material, on lateral surfaces of the NMDD spacers (109) to provide lateral separation between n-type source-drain implanted dopant atoms and the NMOS gate (108). Similarly, PSD spacers (124) have been formed, preferably of the same material as the NSD spacers (123), on lateral surfaces of the PMDD spacers (113) to provide lateral separation between p-type source-drain implanted dopant atoms and the PMOS gate (108). Dimensions of the NSD spacers (123) and PSD spacers (124) may be different to optimize formation of NSD and PSD regions, respectively. N-type dopant atoms (125), such as phosphorus and arsenic, are being implanted into the NMOS transistor (105) at the top surface of the p-well (103) adjacent to the NSD spacers (123), forming an as-implanted NSD region (126) in which a concentration of n-type dopants exceeds a concentration of p-type dopants. Ion implantation of the n-type dopant atoms (125) causes lattice damage to the p-well in the as-implanted NSD region (126). The implanted n-type dopant atoms (125) are blocked from the PMOS transistor (106) by a third photoresist layer (127).

FIG. 1E depicts the IC (100) during a PSD implant. P-type dopant atoms (128), such as boron and/or gallium, are being implanted into the PMOS transistor (106) at the top surface of the n-well (104) adjacent to the PSD spacers (124), forming an as-implanted PSD region (129) in which a concentration of p-type dopants exceeds a concentration of n-type dopants. Ion implantation of the p-type dopant atoms (128) causes lattice damage to the n-well in the as-implanted PSD region (129). The implanted p-type dopant atoms (128) are blocked from the NMOS transistor (105) by a fourth photoresist layer (130).

It is within the scope of the instant invention to exchange the order of the NSD and PSD ion implant operations.

FIG. 1F depicts the IC (100) after a S/D anneal operation to repair the lattice damage in the as-implanted NSD region (126) and in the as-implanted PMDD region (129). In a preferred embodiment, the anneal operation is performed in a rapid thermal processor using known techniques, in order to achieve a high percentage of activation of implanted dopant atoms. This is advantageous because a higher percentage of activation produces a lower series resistance in the transistor, which results in a higher on-state drive current. In the NMOS transistor (105), implanted n-type dopant atoms in the as-implanted NSD region (126) diffuse during the anneal operation, so that a region after anneal in which the concentration of n-type dopant atoms exceeds the concentration of p-type dopants atoms, designated as a post-S/D anneal NSD region (131) extends further into the p-well (103) than the as-implanted NSD region (126). Similarly, in the PMOS transistor (106), implanted p-type dopant atoms in the as-implanted PSD region (129) diffuse during the anneal operation, so that a region after anneal in which the concentration of p-type dopant atoms exceeds the concentration of n-type dopants atoms, designated as a post-S/D anneal PSD region (132) extends further into the n-well (104) than the as-implanted PSD region (129). Similarly, during the S/D anneal operation, the post-MDD anneal NMDD region (121) extends further into the p-well (103) to form a post S/D anneal NMDD region (133), and the post-MDD anneal PMDD region (122) extends further into the n-well (104) to form a post S/D anneal PMDD region (134).

FIG. 1G and FIG. 1H depict the IC during halo ion implant operations. Referring to FIG. 1G, the NSD spacers and PSD spacers have been substantially removed, by known etching operations, to allow halo dopant ion implanted atoms to be placed close to MOS transistor channels. Halo ion implants are typically angled, from 10 to 45 degrees, with respect to a perpendicular axis from a top surface of the IC, to place dopant atoms between MDD implanted dopant atoms and an inversion channel under an MOS transistor gate. Due to shadowing by structures on the IC protruding from the top surface of the IC, such as gates of MOS transistors, halo ion implants are typically divided into two or four implants, in which the angles of the implants are rotated around a perpendicular axis from a top surface of the IC to provide uniform distribution of dopants around the protruding structures. FIG. 1G depicts two NMOS halo ion implant steps. In a first NMOS halo ion implant step, p-type dopant atoms (135), such as boron and/or gallium, are being implanted into the NMOS transistor (105) at the top surface of the p-well (103) adjacent to the NMOS gate (108), forming a first as-implanted NMOS pocket region (137) between an end of the NMDD region (121) under the NMOS gate (108) in which a concentration of p-type dopant atoms exceeds a concentration of n-type dopant atoms. In a second NMOS halo ion implant step, p-type dopant atoms (136), of the same species as the first NMOS halo ion implant (135), are being implanted into the NMOS transistor (105) at the top surface of the p-well (103) adjacent to the NMOS gate (108), forming a second as-implanted NMOS pocket region (138) between an end of the NMDD region (121) under the NMOS gate (108) in which a concentration of p-type dopant atoms exceeds a concentration of n-type dopant atoms. Ion implantation of the p-type dopant atoms (135, 136) causes lattice damage to the p-well in the as-implanted NMOS pocket regions (137, 138). The implanted p-type dopant atoms (135, 136) are blocked from the PMOS transistor (106) by a fifth photoresist layer (139).

FIG. 1H depicts the IC (100) during a PMOS halo ion implant operation, performed in two steps. In a first PMOS halo ion implant step, n-type dopant atoms (140), such as phosphorus and/or arsenic, are being implanted into the PMOS transistor (106) at the top surface of the n-well (104) adjacent to the PMOS gate (112), forming a first as-implanted PMOS pocket region (142) between an end of the PMDD region (122) under the PMOS gate (112) in which a concentration of n-type dopant atoms exceeds a concentration of p-type dopant atoms. In a second PMOS halo ion implant step, n-type dopant atoms (141), of the same species as the first PMOS halo ion implant (140), are being implanted into the PMOS transistor (106) at the top surface of the n-well (104) adjacent to the PMOS gate (112), forming a second as-implanted PMOS pocket region (143) between an end of the PMDD region (122) under the PMOS gate (112) in which a concentration of n-type dopant atoms exceeds a concentration of p-type dopant atoms. Ion implantation of the n-type dopant atoms (140, 141) causes lattice damage to the n-well in the as-implanted PMOS pocket regions (142, 143). The implanted n-type dopant atoms (140, 141) are blocked from the NMOS transistor (105) by a sixth photoresist layer (144).

It is within the scope of the instant invention to exchange the order of the NMOS halo and PMOS halo ion implant operations.

FIG. 1I depicts the IC (100) after a halo anneal operation to repair the lattice damage in the as-implanted NMOS pocket regions and in the as-implanted PMOS pocket regions. In a preferred embodiment, the anneal operation is performed by a laser scan anneal operation using known techniques, or other anneal process that produces diffusion lengths less than 10 nanometers, in order to achieve a low diffusion of implanted dopant atoms. This is advantageous because a lower diffusion length produces a more uniform doping distribution in the transistor channel, which results in a higher on-state drive current, lower off-state leakage current, and reduced DIBL. In the NMOS transistor (105), implanted p-type dopant atoms in the as-implanted NMOS pocket regions diffuse less than 10 nanometers during the halo anneal operation, so that regions after halo anneal in which the concentration of p-type dopant atoms exceeds the concentration of n-type dopants atoms, designated as a post-halo anneal NMOS pocket regions (145, 146) are substantially the same as the as-implanted NMOS pocket regions. Similarly, in the PMOS transistor (106), implanted n-type dopant atoms in the as-implanted PMOS pocket regions diffuse less than 10 nanometers during the halo anneal operation, so that regions after halo anneal in which the concentration of n-type dopant atoms exceeds the concentration of p-type dopants atoms, designated as a post-halo anneal PMOS pocket regions (147, 148) are substantially the same as the as-implanted PMOS pocket regions. Similarly, after the halo anneal operation, dimensions of the post-S/D anneal NMDD region (133), the post-S/D anneal PMDD region (134), the post-S/D anneal NSD region (131) and the post-S/D anneal PSD region (132) are substantially the same as they were before the halo anneal operation.

FIG. 1J depicts the IC (100) after metal silicide is formed on top surfaces of the NMOS source and drain regions and PMOS source and drain regions. NMOS silicide spacers (149) are formed on lateral surfaces of the NMDD spacers (109) to separate metal silicide on the top surface of the NMOS source and drain regions from the NMOS gate (108). PMOS silicide spacers (150) are formed on lateral surfaces of the PMDD spacers (113) to separate metal silicide on the top surface of the PMOS source and drain regions from the PMOS gate (112). In one embodiment, the NMOS silicide spacers (149) and PMOS silicide spacers (150) are formed of silicon dioxide and/or silicon nitride by a process of deposition and anisotropic etchback. In another embodiment, the NMOS silicide spacers (149) and PMOS silicide spacers (150) are formed of low-k dielectric materials, by a process of deposition and anisotropic etchback, to reduce capacitance between the NMOS gate (108) and the NMDD regions (133) and between the PMOS gate (112) and the PMDD regions (134). This is advantageous because reducing capacitance between MOS transistor gates and MDD regions improves switching speeds in digital circuits. In a further embodiment, dimensions of the NMOS silicide spacers (149) and PMOS silicide spacers (150) are not equal. NMOS metal silicide (151) is formed on the top surface of the NMOS source and drain regions, and PMOS metal silicide (152) is formed on the top surface of the PMOS source and drain regions, using known processes.

In a preferred embodiment, lateral dimensions of the NMOS silicide spacers (149) and PMOS silicide spacers (150) are less than lateral dimensions of the NSD spacers (123) and the PSD spacers (124). This is advantageous because series resistances of the NMOS transistor (105) and the PMOS transistor (106) are reduced and leakage currents between the NSD regions (131) and PSD regions (132) are reduced compared to commonly used fabrication processes in which lateral dimensions of source drain spacers and silicide spacers are substantially equal.

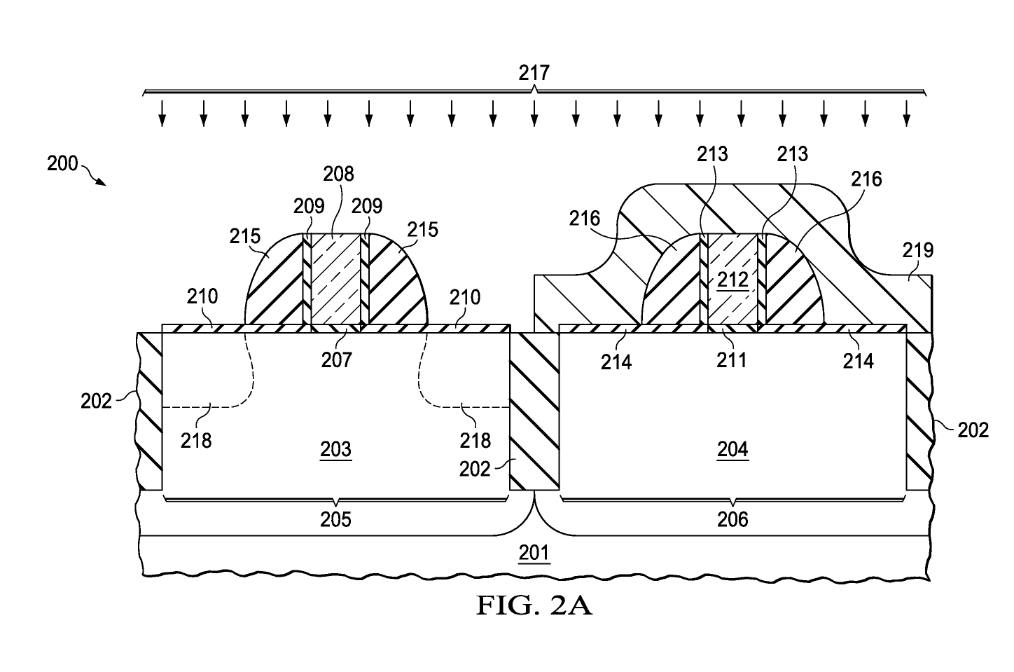

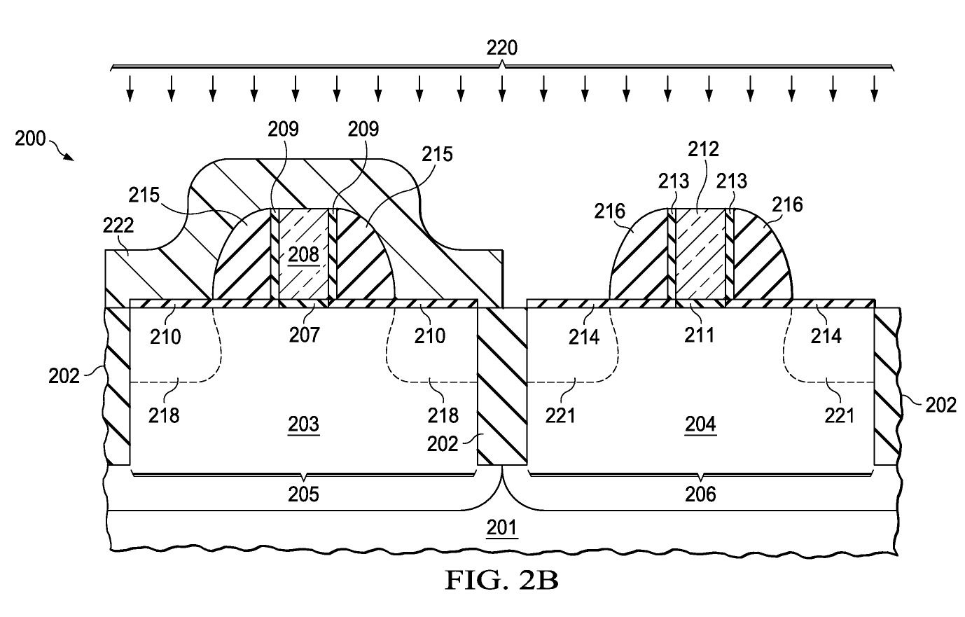

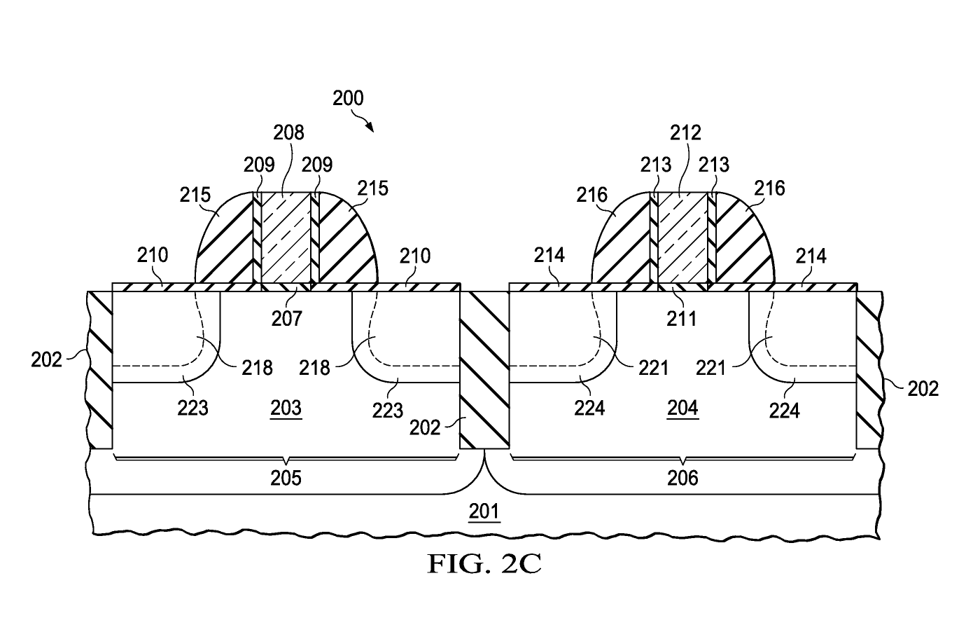

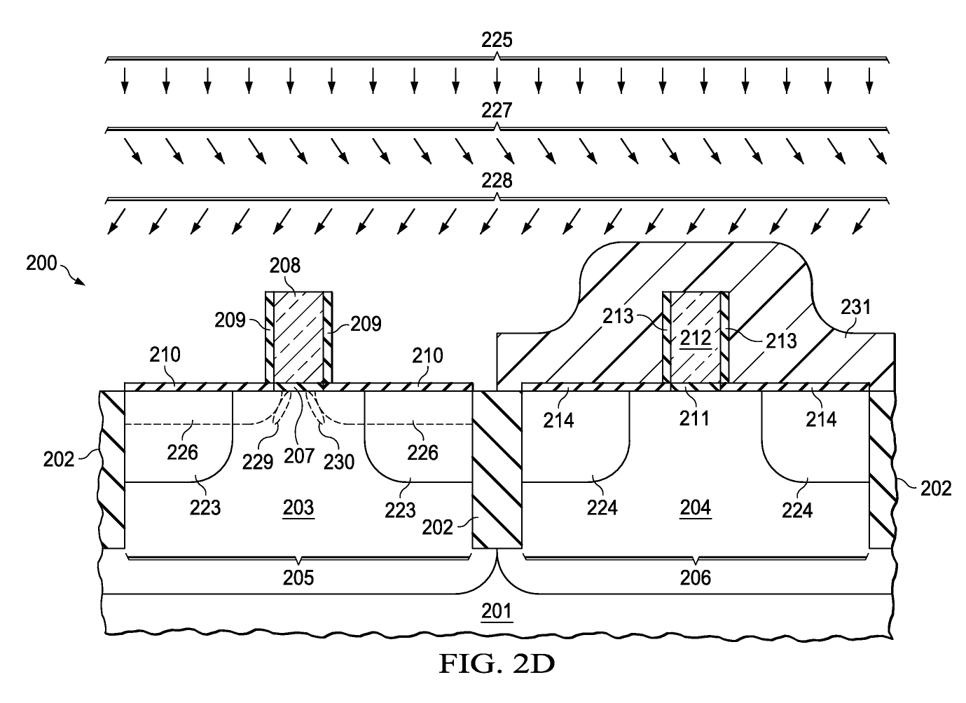

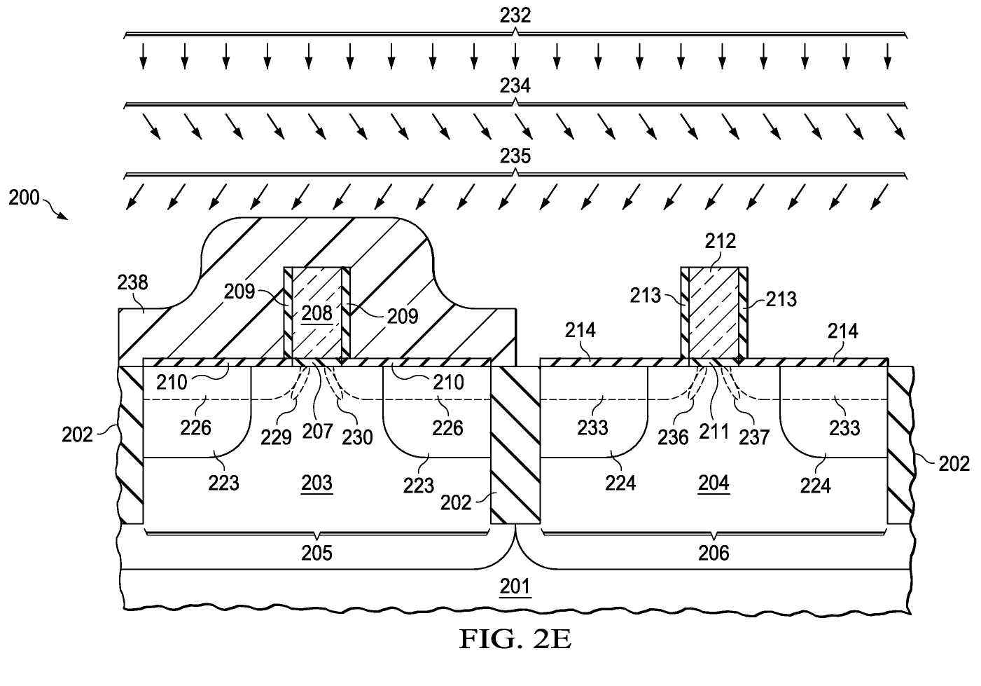

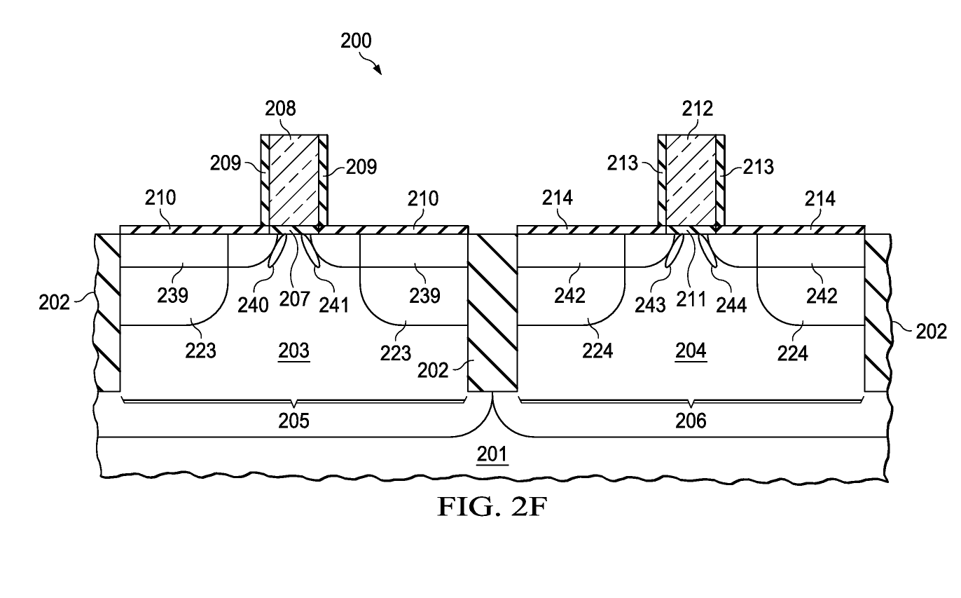

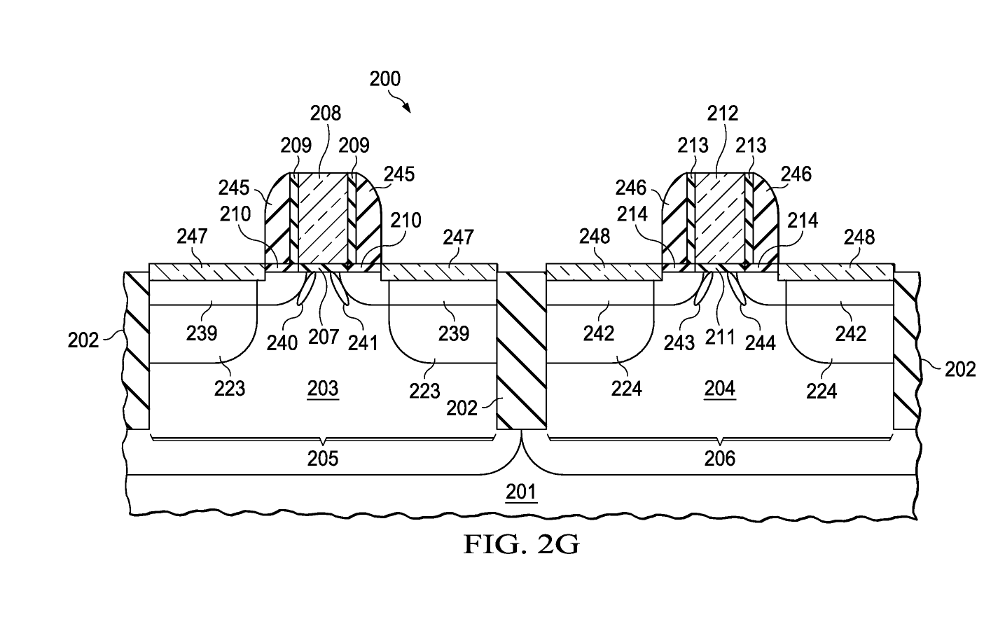

FIG. 2A through FIG. 2G are cross-sections of an integrated circuit (IC) during a process sequence for forming an NMOS transistor and a PMOS transistor according to another embodiment of the instant invention.

FIG. 2A and FIG. 2B depict the IC during S/D ion implant operations. Referring to FIG. 2A, the IC (200) includes a semiconductor substrate (201), in which are formed regions of field oxide (202), typically of silicon dioxide by shallow trench isolation (STI), to electrically isolate components such as transistors in the IC (200). A p-type region known as a p-well (203) is formed in the substrate (201) extending to a top surface of the substrate (201). Similarly, an n-type region known as an n-well (204) is formed in the substrate (201) extending to the top surface of the substrate (201). The p-well (203) and the n-well (204) are separated at the top surface of the substrate (201) by a region of field oxide (202). The NMOS transistor (205) will be formed in a region of the p-well, and the PMOS transistor (206) will be formed in a region of the n-well. The NMOS transistor includes an NMOS gate dielectric (207), typically silicon dioxide, silicon oxy-nitride, hafnium oxide, layers of silicon dioxide and silicon nitride, or other insulating material, an NMOS gate (208), typically polycrystalline silicon, NMDD spacers (209), typically layers of silicon dioxide, silicon nitride or both, formed by oxidation of the NMOS gate (208) or deposition of silicon dioxide or silicon nitride followed by an anisotropic etchback process, on lateral surfaces of the NMOS gate (208). The NMDD spacers (209) are typically less than 20 nanometers thick. A layer of NMOS moat silicon dioxide (210) is on the top surface of the p-well adjacent to the NMOS gate (208). The PMOS transistor includes an PMOS gate dielectric (211), typically silicon dioxide, silicon oxy-nitride, hafnium oxide, layers of silicon dioxide and silicon nitride, or other insulating material, an PMOS gate (212), typically polycrystalline silicon, PMDD spacers (213), typically layers of silicon dioxide, silicon nitride or both, formed by oxidation of the PMOS gate (212) or deposition of silicon dioxide or silicon nitride followed by another anisotropic etchback process, on lateral surfaces of the PMOS gate (212). The PMDD spacers (213) are typically less than 20 nanometers thick. A layer of PMOS moat silicon dioxide (214) is on the top surface of the p-well adjacent to the PMOS gate (212). NSD spacers (215) have been formed of silicon dioxide, silicon nitride, and/or other material, on lateral surfaces of the NMDD spacers (209) to provide lateral separation between n-type source-drain implanted dopant atoms and the NMOS gate (208). Similarly, PSD spacers (216) have been formed, preferably of the same material as the NSD spacers (215), on lateral surfaces of the PMDD spacers (213) to provide lateral separation between p-type source-drain implanted dopant atoms and the PMOS gate (208). Dimensions of the NSD spacers (215) and PSD spacers (216) may be different to optimize formation of NSD and PSD regions, respectively. N-type dopant atoms (217), such as phosphorus and arsenic, are being implanted into the NMOS transistor (105) at the top surface of the p-well (103) adjacent to the NSD spacers (215), forming an as-implanted NSD region (218) in which a concentration of n-type dopants exceeds a concentration of p-type dopants. Ion implantation of the n-type dopant atoms (217) causes lattice damage to the p-well in the as-implanted NSD region (218). The implanted n-type dopant atoms (217) are blocked from the PMOS transistor (106) by a first photoresist layer (219).

FIG. 2B depicts the IC (200) during a PSD implant. P-type dopant atoms (220), such as boron and/or gallium, are being implanted into the PMOS transistor (206) at the top surface of the n-well (204) adjacent to the PSD spacers (216), forming an as-implanted PSD region (221) in which a concentration of p-type dopants exceeds a concentration of n-type dopants. Ion implantation of the p-type dopant atoms (220) causes lattice damage to the n-well in the as-implanted PSD region (221). The implanted p-type dopant atoms (220) are blocked from the NMOS transistor (205) by a second photoresist layer (222).

It is within the scope of the instant invention to exchange the order of the NSD and PSD ion implant operations.

FIG. 2C depicts the IC (200) after a S/D anneal operation to repair the lattice damage in the as-implanted NSD region (218) and in the as-implanted PMDD region (221). In a preferred embodiment, the anneal operation is performed in a rapid thermal processor using known techniques, in order to achieve a high percentage of activation of implanted dopant atoms. This is advantageous because a higher percentage of activation produces a lower series resistance in the transistor, which results in a higher on-state drive current. In the NMOS transistor (205), implanted n-type dopant atoms in the as-implanted NSD region (218) diffuse during the anneal operation, so that a region after anneal in which the concentration of n-type dopant atoms exceeds the concentration of p-type dopants atoms, designated as a post-S/D anneal NSD region (223) extends further into the p-well (203) than the as-implanted NSD region (218). Similarly, in the PMOS transistor (106), implanted p-type dopant atoms in the as-implanted PSD region (221) diffuse during the anneal operation, so that a region after anneal in which the concentration of p-type dopant atoms exceeds the concentration of n-type dopants atoms, designated as a post-S/D anneal PSD region (224) extends further into the n-well (204) than the as-implanted PSD region (221).

FIG. 2D and FIG. 2E depict the IC during MDD and halo ion implant operations. Referring to FIG. 2D, the NSD spacers and PSD spacers have been substantially removed, by known etching operations, to allow halo dopant ion implanted atoms and MDD ion implanted atoms to be placed close to MOS transistor channels. N-type dopant atoms (225), such as phosphorus and arsenic, are being implanted into the NMOS transistor (205) at the top surface of the p-well (203) adjacent to the NMOS gate (208), forming an as-implanted NMDD region (226) in which a concentration of n-type dopants exceeds a concentration of p-type dopants. Ion implantation of the n-type dopant atoms (225) causes lattice damage to the p-well in the as-implanted NMDD region (226).

Still referring to FIG. 2D, halo ion implants are typically angled, from 10 to 45 degrees, with respect to a perpendicular axis from a top surface of the IC, to place dopant atoms between MDD implanted dopant atoms and an inversion channel under an MOS transistor gate. Due to shadowing by structures on the IC protruding from the top surface of the IC, such as gates of MOS transistors, halo ion implants are typically divided into two or four implants, in which the angles of the implants are rotated around a perpendicular axis from a top surface of the IC to provide uniform distribution of dopants around the protruding structures. FIG. 2D depicts two NMOS halo ion implant steps. In a first NMOS halo ion implant step, p-type dopant atoms (227), such as boron and/or gallium, are being implanted into the NMOS transistor (205) at the top surface of the p-well (203) adjacent to the NMOS gate (208), forming a first as-implanted NMOS pocket region (229) between an end of the as-implanted NMDD region (226) under the NMOS gate (208) in which a concentration of p-type dopant atoms exceeds a concentration of n-type dopant atoms. In a second NMOS halo ion implant step, p-type dopant atoms (228), of the same species as the first NMOS halo ion implant (227), are being implanted into the NMOS transistor (205) at the top surface of the p-well (203) adjacent to the NMOS gate (208), forming a second as-implanted NMOS pocket region (230) between an end of the as-implanted NMDD region (226) under the NMOS gate (208) in which a concentration of p-type dopant atoms exceeds a concentration of n-type dopant atoms. Ion implantation of the p-type dopant atoms (227, 228) causes lattice damage to the p-well in the as-implanted NMOS pocket regions (229, 230). The implanted n-type dopant atoms (225) and the implanted p-type dopant atoms (227, 228) are blocked from the PMOS transistor (206) by a third photoresist layer (231).

Referring to FIG. 2E, P-type dopant atoms (232), such as boron and/or gallium, are being implanted into the PMOS transistor (206) at the top surface of the n-well (204) adjacent to the PMOS gate (212), forming an as-implanted PMDD region (233) in which a concentration of p-type dopants exceeds a concentration of n-type dopants. Ion implantation of the p-type dopant atoms (232) causes lattice damage to the n-well in the as-implanted PMDD region (233).

Still referring to FIG. 2E, two PMOS halo ion implant steps are depicted. In a first PMOS halo ion implant step, n-type dopant atoms (234), such as phosphorus and/or arsenic, are being implanted into the PMOS transistor (206) at the top surface of the n-well (204) adjacent to the PMOS gate (212), forming a first as-implanted PMOS pocket region (236) between an end of the as-implanted PMDD region (233) under the PMOS gate (212) in which a concentration of n-type dopant atoms exceeds a concentration of p-type dopant atoms. In a second PMOS halo ion implant step, n-type dopant atoms (235), of the same species as the first PMOS halo ion implant (234), are being implanted into the PMOS transistor (206) at the top surface of the n-well (204) adjacent to the PMOS gate (212), forming a second as-implanted PMOS pocket region (237) between an end of the as-implanted PMDD region (233) under the PMOS gate (212) in which a concentration of n-type dopant atoms exceeds a concentration of p-type dopant atoms. Ion implantation of the n-type dopant atoms (234, 235) causes lattice damage to the n-well in the as-implanted PMOS pocket regions (236, 237). The implanted p-type dopant atoms (232) and the implanted n-type dopant atoms (234, 235) are blocked from the NMOS transistor (205) by a fourth photoresist layer (238).

It is within the scope of the instant invention to exchange the order of the NMOS halo and PMOS MDD and halo ion implant operations.

FIG. 2F depicts the IC (200) after an MDD/halo anneal operation to repair the lattice damage in the as-implanted NMDD regions, the as-implanted NMOS pocket regions, the as-implanted PMDD regions, and in the as-implanted PMOS pocket regions. In a preferred embodiment, the anneal operation is performed by a laser scan anneal operation using known techniques, or other anneal process that produces diffusion lengths less than 10 nanometers, in order to achieve a low diffusion of implanted dopant atoms. This is advantageous because a lower diffusion length produces a more uniform doping distribution in the transistor channel, which results in a higher on-state drive current, lower off-state leakage current, and reduced DIBL. In the NMOS transistor (205), implanted n-type dopant atoms in the as-implanted NMDD regions diffuse less than 10 nanometers during the MDD/halo anneal operation, so that regions after MDD/halo anneal in which the concentration of n-type dopant atoms exceeds the concentration of p-type dopants atoms, designated as a post-MDD/halo anneal NMDD regions (239) are substantially the same as the as-implanted NMDD regions. As well, implanted p-type dopant atoms in the as-implanted NMOS pocket regions diffuse less than 10 nanometers during the MDD/halo anneal operation, so that regions after MDD/halo anneal in which the concentration of p-type dopant atoms exceeds the concentration of n-type dopants atoms, designated as a post-MDD/halo anneal NMOS pocket regions (240, 241) are substantially the same as the as-implanted NMOS pocket regions. Similarly, in the PMOS transistor (106), implanted p-type dopant atoms in the as-implanted PMDD regions diffuse less than 10 nanometers during the MDD/halo anneal operation, so that regions after MDD/halo anneal in which the concentration of p-type dopant atoms exceeds the concentration of n-type dopants atoms, designated as a post-MDD/halo anneal PMDD regions (242) are substantially the same as the as-implanted PMDD regions. As well, implanted n-type dopant atoms in the as-implanted PMOS pocket regions diffuse less than 10 nanometers during the MDD/halo anneal operation, so that regions after MDD/halo anneal in which the concentration of n-type dopant atoms exceeds the concentration of p-type dopants atoms, designated as a post-halo anneal PMOS pocket regions (243, 244) are substantially the same as the as-implanted PMOS pocket regions. Similarly, after the MDD/halo anneal operation, the dimensions of the post-S/D anneal NMDD region (223), and the post-S/D anneal PSD region (224) are substantially the same as they were before the MDD/halo anneal operation.

FIG. 2G depicts the IC (200) after metal silicide is formed on top surfaces of the NMOS source and drain regions and PMOS source and drain regions. NMOS silicide spacers (245) are formed on lateral surfaces of the NMDD spacers (209) to separate metal silicide on the top surface of the NMOS source and drain regions from the NMOS gate (208). PMOS silicide spacers (246) are formed on lateral surfaces of the PMDD spacers (213) to separate metal silicide on the top surface of the PMOS source and drain regions from the PMOS gate (212). In one embodiment, the NMOS silicide spacers (245) and PMOS silicide spacers (246) are formed of silicon dioxide and/or silicon nitride by a process of deposition and anisotropic etchback. In another embodiment, the NMOS silicide spacers (245) and PMOS silicide spacers (246) are formed of low-k dielectric materials, by a process of deposition and anisotropic etchback, to reduce capacitance between the NMOS gate (208) and the NMDD regions (239) and between the PMOS gate (212) and the PMDD regions (242). This is advantageous because reducing capacitance between MOS transistor gates and MDD regions improves switching speeds in digital circuits. In a further embodiment, dimensions of the NMOS silicide spacers (245) and PMOS silicide spacers (246) are not equal. NMOS metal silicide (247) is formed on the top surface of the NMOS source and drain regions, and PMOS metal silicide (248) is formed on the top surface of the PMOS source and drain regions, using known processes.

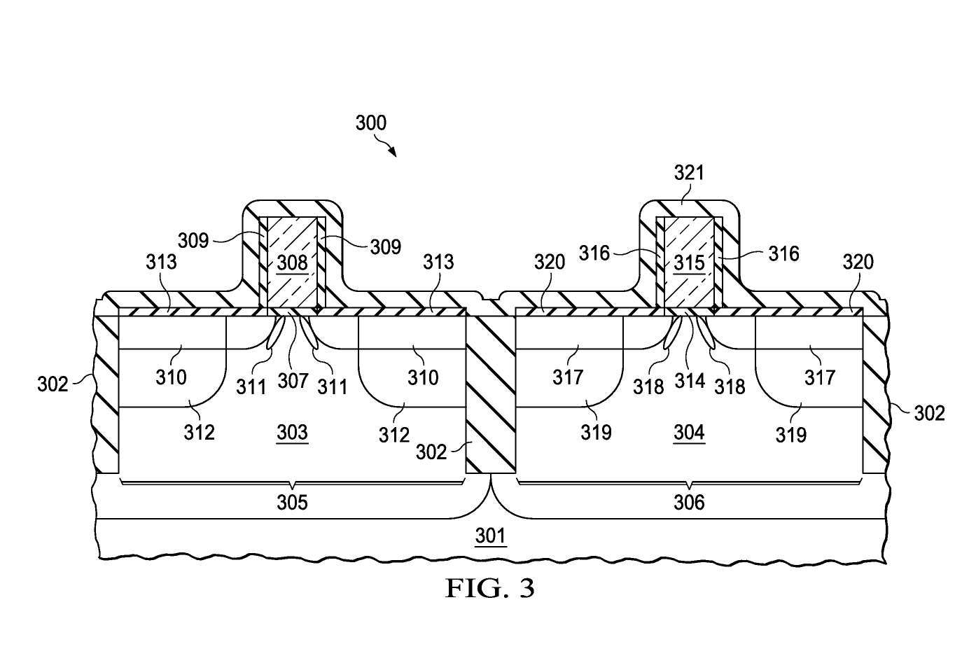

FIG. 3 is a cross-section of an IC with NMOS and PMOS transistors, after formation of NSD, PSD, NMDD, PMDD, NMOS pocket and PMOS pocket elements, in which a stress layer is applied to the NMOS and PMOS transistors, in a further embodiment of the instant invention. The IC (300) includes a semiconductor substrate (301), in which are formed regions of field oxide (302), typically of silicon dioxide by shallow trench isolation (STI), to electrically isolate components such as transistors in the IC (300). A p-type region known as a p-well (303) is formed in the substrate (301) extending to a top surface of the substrate (301). Similarly, an n-type region known as an n-well (304) is formed in the substrate (301) extending to the top surface of the substrate (301). The p-well (303) and the n-well (304) are separated at the top surface of the substrate (301) by a region of field oxide (302). The NMOS transistor (305) will be formed in a region of the p-well (303), and the PMOS transistor (306) will be formed in a region of the n-well (304). The NMOS transistor (305) includes an NMOS gate dielectric (307), typically silicon dioxide, silicon oxy-nitride, hafnium oxide, layers of silicon dioxide and silicon nitride, or other insulating material, an NMOS gate (308), typically polycrystalline silicon, NMDD spacers (309), typically layers of silicon dioxide, silicon nitride or both, formed by oxidation of the NMOS gate (308) or deposition of silicon dioxide or silicon nitride followed by an anisotropic etchback process, on lateral surfaces of the NMOS gate (308). The NMDD spacers (309) are typically less than 20 nanometers thick. NMDD (310) regions, NMOS pocket (311) regions and NSD (312) regions have been formed according to an embodiment of the instant invention. A layer of NMOS moat silicon dioxide (313) is on the top surface of the p-well adjacent to the NMOS gate (308). The PMOS transistor (306) includes an PMOS gate dielectric (314), typically silicon dioxide, silicon oxy-nitride, hafnium oxide, layers of silicon dioxide and silicon nitride, or other insulating material, an PMOS gate (315), typically polycrystalline silicon, PMDD spacers (316), typically layers of silicon dioxide, silicon nitride or both, formed by oxidation of the PMOS gate (315) or deposition of silicon dioxide or silicon nitride followed by another anisotropic etchback process, on lateral surfaces of the PMOS gate (315). The PMDD spacers (316) are typically less than 20 nanometers thick. PMDD (317) regions, PMOS pocket (318) regions and PSD (319) regions have been formed according to an embodiment of the instant invention. A layer of PMOS moat silicon dioxide (320) is on the top surface of the p-well adjacent to the PMOS gate (315). A stress layer (321), preferably silicon nitride greater than 10 nm thick, is formed on a top surface of the NMOS and PMOS transistors (305, 306). The stress layer (321) has a compressive stress greater than 1000 MPa. Compressive stress is transferred to the NMOS gate (308) and PMOS gate (315). In subsequent fabrication steps of the IC (300), the stress layer (321) is removed. The NMOS gate (307) and the PMOS gate (315) retain a significant portion of the compressive stress that was acquired during formation of the stress layer (321). The formation of the stress layer prior to formation of silicide spacers is advantageous because a higher amount of compressive stress is retained by the NMOS gate (307) and the PMOS gate (315) compared to commonly used fabrication sequences in which a stress layer is applied to MOS transistors after spacers for silicidation are in place. Compressive stress enhances MOS transistor on-state drive current.

In an alternate embodiment, a stress layer may be deposited after removal of material from NSD spacers and PSD spacers, and before formation of silicide spacers.

What is claimed is:

1. A method of forming an integrated circuit, comprising the steps of:
providing a semiconductor substrate;
forming a p-type well in said semiconductor substrate at a top surface of said semiconductor substrate;
forming an n-type well in said semiconductor substrate at said top surface of said semiconductor substrate;
forming a gate dielectric layer on a top surface of said n-type well and a top surface of said p-type well;
forming an n-channel MOS transistor gate on a top surface of said gate dielectric layer over said p-type well;
forming an p-channel MOS transistor gate on a top surface of said gate dielectric layer over said n-type well;
forming NMDD spacers less than 20 nm thick on lateral surfaces of said n-channel MOS transistor gate;
ion implanting a first set of n-type dopant atoms into said p-type well adjacent to said n-channel MOS transistor gate;
forming PMDD spacers less than 20 nm thick on lateral surfaces of said p-channel MOS transistor gate;
ion implanting a first set of p-type dopant atoms into said n-type well adjacent to said p-channel MOS transistor gate;
annealing said semiconductor substrate so that any damage to said semiconductor substrate from said step of ion implanting said first set of n-type dopant atoms and said step of ion implanting said first set of p-type dopant atoms is substantially repaired;
forming NSD spacers more than 30 nm thick on lateral surfaces of said n-channel MOS transistor gate;
ion implanting a second set of n-type dopants into said p-type well adjacent to said NSD spacers;
forming PSD spacers more than 30 nm thick on lateral surfaces of said p-channel MOS transistor gate;
ion implanting a second set of p-type dopants into said n-type well adjacent to said PSD spacers;
annealing said semiconductor substrate so that any damage to said semiconductor substrate from said step of ion implanting said second set of n-type dopant atoms and said step of ion implanting said second set of p-type dopant atoms is substantially repaired;
removing material from said NSD spacers by an etching process;
ion implanting a third set of p-type dopants into said p-type well adjacent to said n-channel MOS transistor gate after said step of removing material from said NSD spacers;
removing material from said PSD spacers by an etching process;
ion implanting a third set of n-type dopants into said n-type well adjacent to said p-channel MOS transistor gate after said step of removing material from said PSD spacers;
annealing said semiconductor substrate so that any damage to said semiconductor substrate from said step of ion implanting said third set of p-type dopant atoms and said step of ion implanting said third set of n-type dopant atoms is substantially repaired;
forming a first set of silicide spacers on lateral surfaces of said n-channel MOS transistor gate;
forming a second set of silicide spacers on lateral surfaces of said p-channel MOS transistor gate; and
forming a metal silicide layer on said top surface of said p-type well adjacent to said first set of silicide spacers and on said top surface of said n-type well adjacent to said second set of silicide spacers

2. The method of claim 1, in which said first set of silicide spacers and second set of silicide spacers are formed of low-k dielectric material.

3. The method of claim 1, in which:
lateral dimensions of said NSD spacers are greater than lateral dimensions of said first set of silicide spacers; and
lateral dimensions of said PSD spacers are greater than lateral dimensions of said second set of silicide spacers.

4. The method of claim 3, further comprising the step of forming a stress layer on a top surface of said n-channel MOS transistor gate and a top surface of said p-channel MOS transistor gate.

5. The method of claim 4, in which said stress layer has a compressive stress greater then 1000 MPa.

6. The method of claim 5, in which said stress layer is substantially composed of silicon nitride.

7. The method of claim 6, in which said step of forming a stress layer is performed after said steps of removing material from said NSD spacers and removing material from said PSD spacers, and before said steps of forming a first set of silicide spacers and forming a second set of silicide spacers.

8. A method of forming an integrated circuit, comprising the steps of:
providing a semiconductor substrate;
forming a p-type well in said semiconductor substrate at a top surface of said semiconductor substrate;
forming an n-type well in said semiconductor substrate at said top surface of said semiconductor substrate;
forming a gate dielectric layer on a top surface of said n-type well and a top surface of said p-type well;
forming an n-channel MOS transistor gate on a top surface of said gate dielectric layer over said p-type well;
forming an p-channel MOS transistor gate on a top surface of said gate dielectric layer over said n-type well;
forming NSD spacers more than 30 nm thick on lateral surfaces of said n-channel MOS transistor gate;
ion implanting a first set of n-type dopants into said p-type well adjacent to said NSD spacers;
forming PSD spacers more than 30 nm thick on lateral surfaces of said p-channel MOS transistor gate;
ion implanting a first set of p-type dopants into said n-type well adjacent to said PSD spacers;
annealing said semiconductor substrate so that any damage to said semiconductor substrate from said step of ion implanting said second set of n-type dopant atoms and said step of ion implanting said second set of p-type dopant atoms is substantially repaired;
removing material from said NSD spacers by an etching process;
forming NMDD spacers less than 20 nm thick on lateral surfaces of said n-channel MOS transistor gate;
ion implanting a second set of n-type dopant atoms into said p-type well adjacent to said n-channel MOS transistor gate after said step of removing material from said NSD spacers;
ion implanting a third set of p-type dopants into said p-type well adjacent to said n-channel MOS transistor gate after said step of removing material from said NSD spacers;
removing material from said PSD spacers by an etching process;
forming PMDD spacers less than 20 nm thick on lateral surfaces of said p-channel MOS transistor gate;
ion implanting a second set of p-type dopant atoms into said n-type well adjacent to said p-channel MOS transistor gate after said step of removing material from said PSD spacers;
ion implanting a third set of n-type dopants into said n-type well adjacent to said p-channel MOS transistor gate after said step of removing material from said PSD spacers;
annealing said semiconductor substrate so that any damage to said semiconductor substrate from said step of ion implanting said third set of p-type dopant atoms and said step of ion implanting said third set of n-type dopant atoms is substantially repaired;
forming a first set of silicide spacers on lateral surfaces of said n-channel MOS transistor gate;
forming a second set of silicide spacers on lateral surfaces of said p-channel MOS transistor gate; and
forming a metal silicide layer on said top surface of said p-type well adjacent to said first set of silicide spacers and on said top surface of said n-type well adjacent to said second set of silicide spacers.

9. The method of claim 8, in which said first set of silicide spacers and second set of silicide spacers are formed of low-k dielectric material.

10. The method of claim 8, in which:
lateral dimensions of said NSD spacers are greater than lateral dimensions of said first set of silicide spacers; and
lateral dimensions of said PSD spacers are greater than lateral dimensions of said second set of silicide spacers.

11. The method of claim 10, further comprising the step of forming a stress layer on a top surface of said n-channel MOS transistor gate and a top surface of said p-channel MOS transistor gate.

12. The method of claim 11, in which said stress layer has a compressive stress greater then 1000 MPa.

13. The method of claim 12, in which said stress layer is substantially composed of silicon nitride.

14. The method of claim 13, in which said step of forming a stress layer is performed after said steps of removing material from said NSD spacers and removing material from said PSD spacers, and before said steps of forming a first set of silicide spacers and forming a second set of silicide spacers.

15. An integrated circuit comprising:
provided a semiconductor substrate;
a p-type well formed in said semiconductor substrate at a top surface of said semiconductor substrate;
an n-type well formed in said semiconductor substrate at a top surface of said semiconductor substrate;
an NMOS transistor formed in said p-type well, further comprising;
a first gate dielectric layer formed on said top surface of said p-type well;
an NMOS gate formed on a top surface of said first gate dielectric layer;
n-type NMDD regions formed in said p-type well adjacent to said NMOS gate;
p-type NMOS pocket regions formed in said p-type well between said n-type NMDD regions and a channel region under said NMOS gate;
n-type NSD regions formed in said p-type well adjacent to said n-type NMDD regions; and
a first set of metal silicide layers on a top surface of said n-type NSD regions and on a portion of a top surface of said n-type NMDD regions such that a lateral separation between the first set of metal silicide layers and said NMOS gate is less than a lateral separation between said n-type NSD regions and said NMOS gate;
and
a PMOS transistor formed in said n-type well, further comprising;
a second gate dielectric layer formed on said top surface of said n-type well;
a PMOS gate formed on a top surface of said second gate dielectric layer;
p-type PMDD regions formed in said n-type well adjacent to said PMOS gate;
n-type PMOS pocket regions formed in said n-type well between said p-type PMDD regions and a channel region under said PMOS gate;
p-type PSD regions formed in said n-type well adjacent to said p-type PMDD regions; and
a second set of metal silicide layers on a top surface of said p-type PSD regions and on a portion of a top surface of said p-type PMDD regions such that a lateral separation between the second set of metal silicide layers and said PMOS gate is less than a lateral separation between said p-type PSD regions and said PMOS gate.

16. The integrated circuit of claim 15, further comprising:
a first set of spacers formed on lateral surfaces of said NMOS gate, comprised of a low-k dielectric material; and
a second set of spacers formed on lateral surfaces of said PMOS gate, comprised of a low-k dielectric material.

17. The integrated circuit of claim 16, in which said low-k dielectric material is organo-silicate glass.

18. The integrated circuit of claim 16, in which said low-k dielectric material is formed from methylsilsesquioxane.

19. The integrated circuit of claim 16, in which said low-k dielectric material is carbon doped silicon dioxide.
